(19) United States
(12) Patent Application Publication
(10) Pub. No.: US 2026/0130031 A1
(43) Pub. Date: May 7, 2026

(54) DISPLAY DEVICE

(71) Applicant: AUO Corporation, Hsinchu City (TW)

(72) Inventors: Yung-Da Chen, Hsinchu City (TW); Yu Chun Yen, Hsinchu City (TW); Wen-Tai Chen, Hsinchu City (TW); Yu-Sheng Huang, Hsinchu City (TW); Chien-Sen Weng, Hsinchu City (TW)

(73) Assignee: AUO Corporation, Hsinchu City (TW)

(21) Appl. No.: 19/226,170

(22) Filed: Jun. 3, 2025

(30) Foreign Application Priority Data
Nov. 1, 2024 (TW) 113141990

(51) Int. Cl. H10H 29/49; H10H 29/39

(52) U.S. Cl. CPC H10H 29/49; H10H 29/39

(57) ABSTRACT

A display device includes a substrate, first chip connection line structures, light emitting elements, a first insulating layer, a failed microchip, second chip connection line structures, and a repair microchip. The first chip connection line structures are located above the substrate and extends outward from a chip placement area. The first insulating layer is located above the substrate and laterally surrounds the failed microchip. The failed microchip is at least partially connected to the first chip connection line structures. The second chip connection line structures are located above the first insulating layer. At least a part of the second chip connection line structures is electrically connected to the first chip connection line structures. The repair microchip is located on the first insulating layer. The repair microchip at least partially overlaps with the failed microchip and is electrically connected to the light emitting elements through the second chip connection line structures.

### CROSS-REFERENCE TO RELATED APPLICATION

This application claims the priority benefit of Taiwan application serial no. 113141990, filed on Nov. 1, 2024. The entirety of the above-mentioned patent application is hereby incorporated by reference herein and made a part of this specification.

### BACKGROUND

### Technical Field

The disclosure relates to a display device, and more particularly to a display device including a repair microchip.

### Description of Related Art

The micro light emitting diode (μLED) display panel is a display technology composed of tens of thousands of micro light emitting diodes. The micro light emitting diodes serve as light sources for pixels and have higher brightness, lower power consumption, and longer lifespan than traditional organic light emitting diode display panels or liquid crystal display panels.

In the micro light emitting diode display panel, the driving manner of the micro light emitting diodes is a key challenge because each micro light emitting diode requires precise signal control. Using microchip technology, microcontroller chips may be disposed in a display area of the display panel. The microchips directly provide signals to the micro light emitting diodes to drive and control the pixels. This technology greatly improves the precision and efficiency of signal transmission, while reducing the layout complexity of a driving circuit, which is conducive to the implementation of miniaturization and a high-resolution display panel.

### SUMMARY

The disclosure provides a display device, which may repair a failed microchip.

At least one embodiment of the disclosure provides a display device, which includes a substrate, multiple first chip connection line structures, multiple light emitting elements, a first insulating layer, a failed microchip, multiple second chip connection line structures, and a repair microchip. The first chip connection line structures are located above the substrate and extend outward from a chip placement area. The light emitting elements are respectively disposed in multiple pixel areas. The first insulating layer is located above the substrate. The failed microchip is located in the chip placement area. The first insulating layer laterally surrounds the failed microchip, and the failed microchip is at least partially connected to the first chip connection line structures. The second chip connection line structures are located above the first insulating layer, and at least a part of the second chip connection line structures is electrically connected to the first chip connection line structures. The repair microchip is located above the first insulating layer. The repair microchip is located in the chip placement area and at least partially overlaps with the failed microchip. The repair microchip is electrically connected to the light emitting elements through the second chip connection line structures.

At least one embodiment of the disclosure provides a display device, which includes a substrate, multiple light emitting elements, a first insulating layer, a first microchip, a second microchip, and a first chip connection line structure. The light emitting elements are respectively disposed in multiple pixel areas around a chip placement area. The first insulating layer is located above the substrate. The first microchip is located in the chip placement area. The first insulating layer laterally surrounds the first microchip. The second microchip is located above the first insulating layer. The second microchip is located in the chip placement area and at least partially overlaps with the first microchip. The second microchip is electrically connected to the light emitting elements. The first chip connection line structure is cut to have a first part and a second part separated from each other. The first microchip is electrically connected to the first part, and the second microchip is electrically connected to the second part.

### BRIEF DESCRIPTION OF THE DRAWINGS

FIG. 1A, FIG. 2A, FIG. 3A, FIG. 4A, FIG. 5A, and FIG. 6A are top schematic views of various stages of manufacturing a display device according to an embodiment of the disclosure. FIG. 1B, FIG. 2B, FIG. 3B, FIG. 4B, FIG. 5B, and FIG. 6B are respectively cross-sectional schematic views taken along a line A-A′ and a line B-B′ of FIG. 1A, FIG. 2A, FIG. 3A,

FIG. 4A, FIG. 5A, and FIG. 6A.

FIG. 7A, FIG. 8A, and FIG. 9A are top schematic views of various stages of manufacturing a display device according to an embodiment of the disclosure.

FIG. 7B, FIG. 8B, and FIG. 9B are respectively cross-sectional schematic views taken along a line A-A′ and a line B-B′ of FIG. 7A, FIG. 8A, and FIG. 9A.

FIG. 10A, FIG. 11A, FIG. 12A, FIG. 13A, FIG. 14A, and FIG. 15A are top schematic views of various stages of manufacturing a display device according to an embodiment of the disclosure.

FIG. 10B, FIG. 11B, FIG. 12B, FIG. 13B, FIG. 14B, and FIG. 15B are respectively cross-sectional schematic views taken along a line A-A′ and a line B-B′ of FIG. 10A, FIG. 11A, FIG. 12A, FIG. 13A, FIG. 14A, and FIG. 15A.

FIG. 16 is a cross-sectional schematic view of manufacturing a display device according to an embodiment of the disclosure.

### DESCRIPTION OF THE EMBODIMENTS

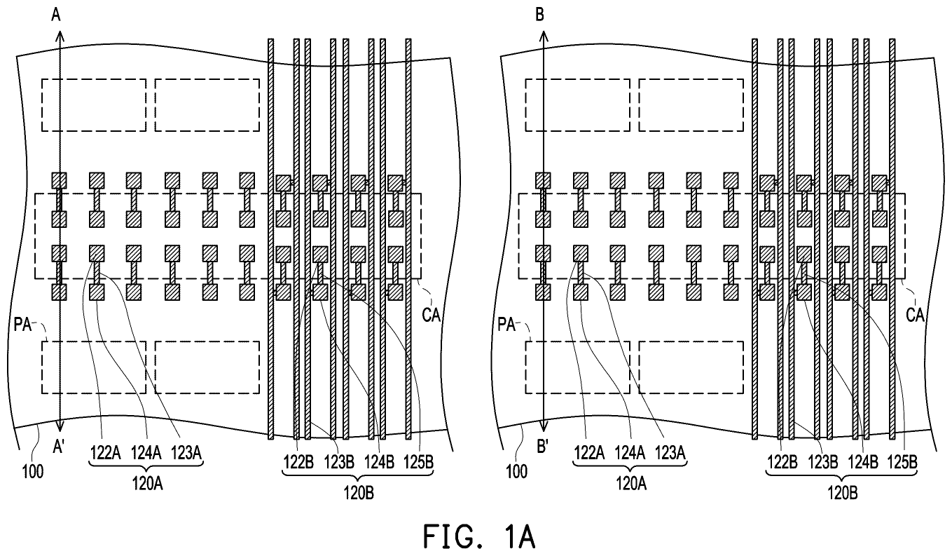

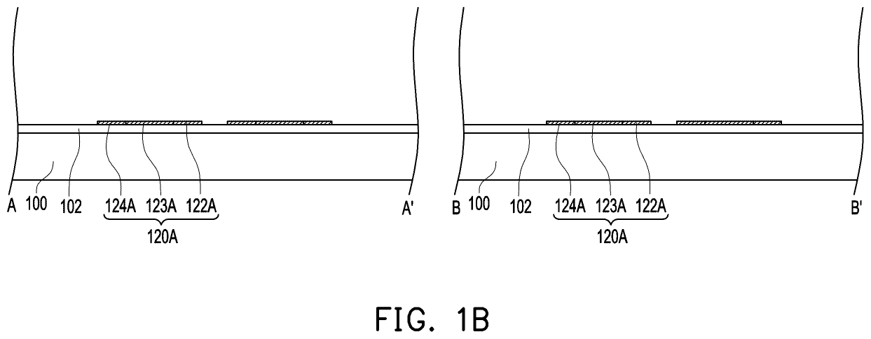

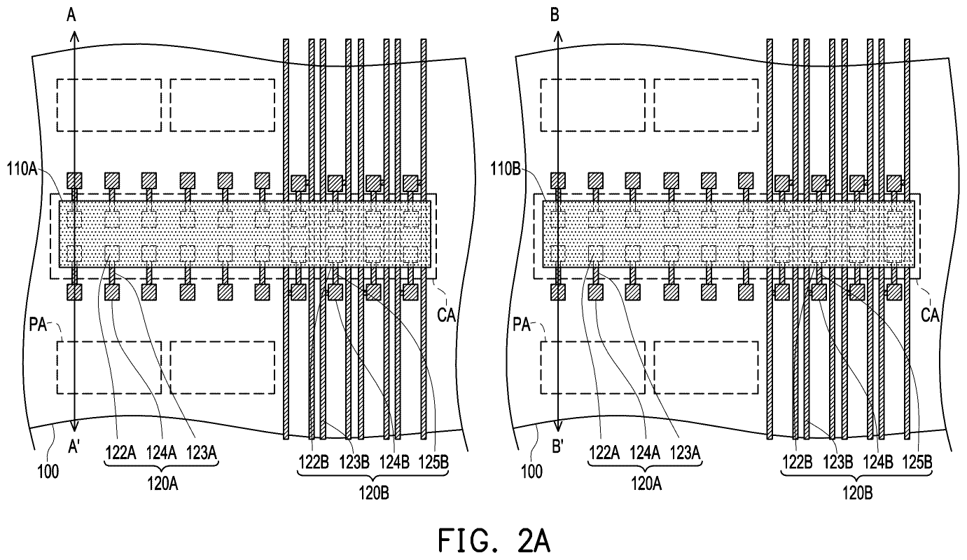

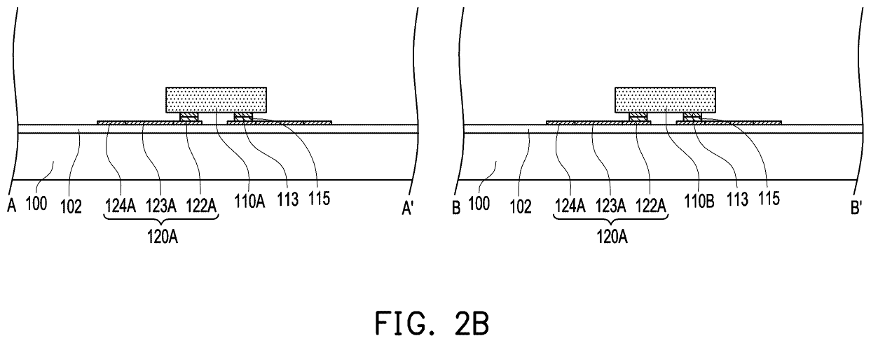

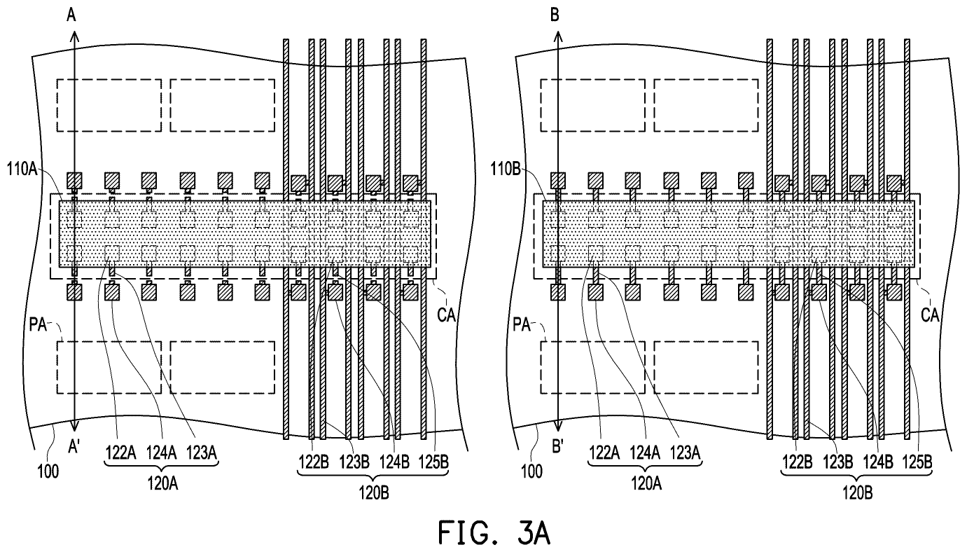

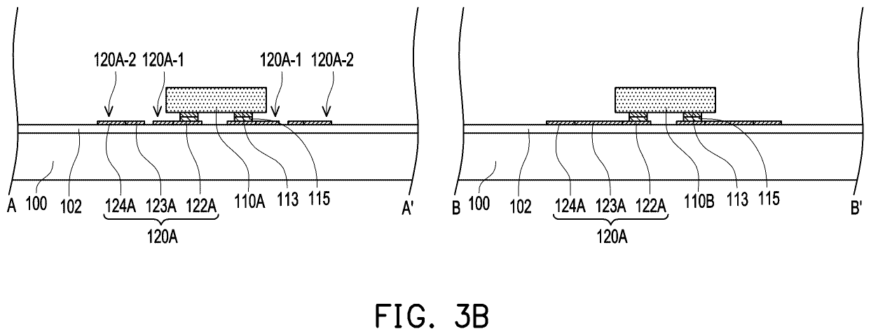

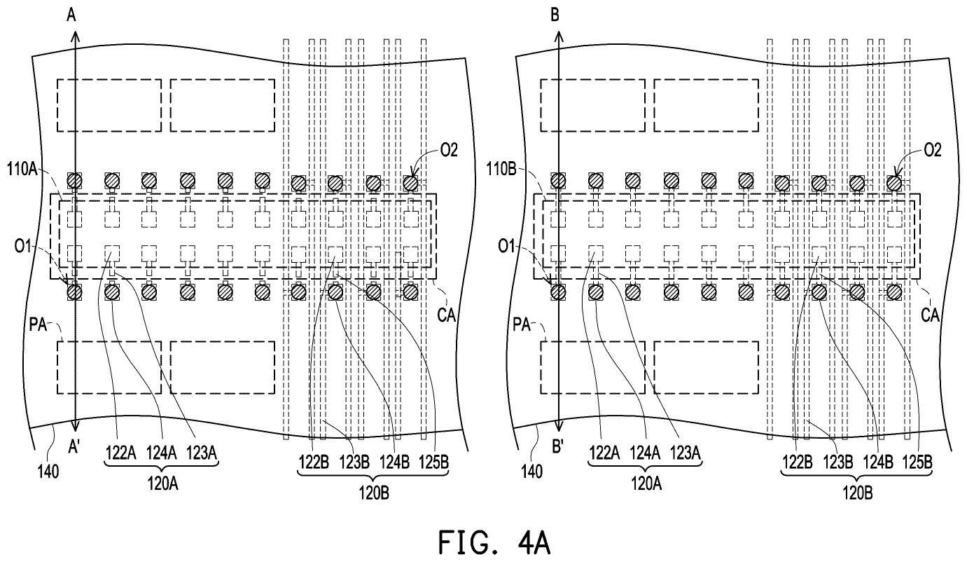

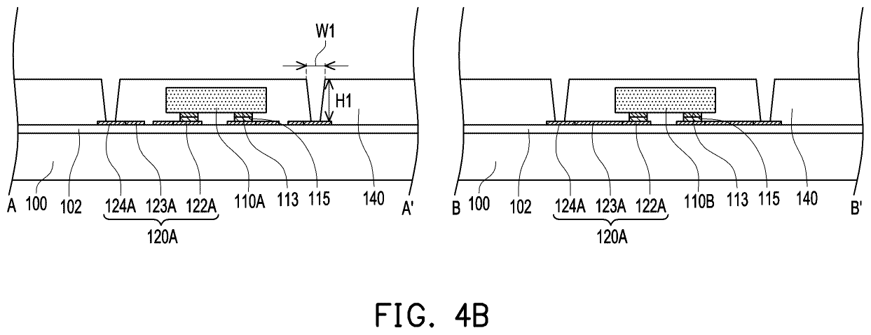

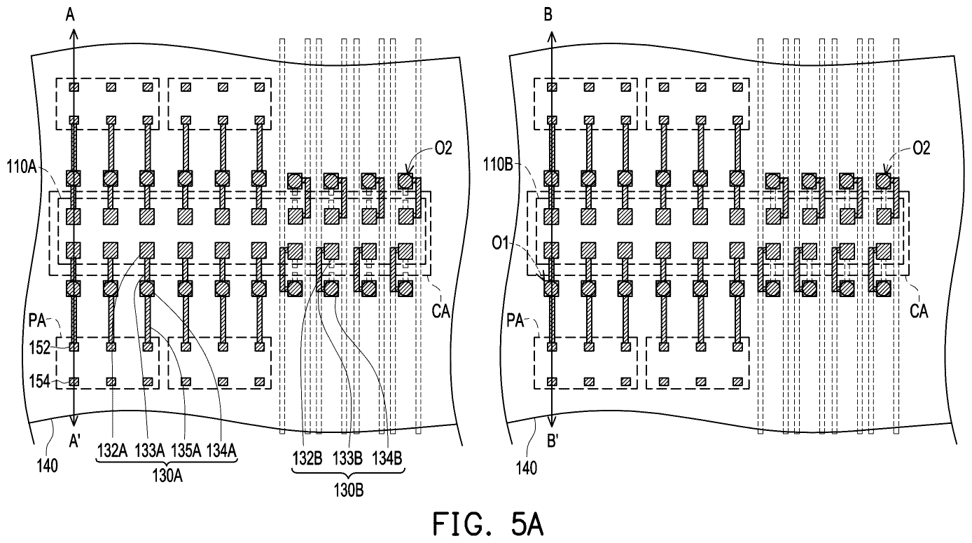

FIG. 1A, FIG. 2A, FIG. 3A, FIG. 4A, FIG. 5A, and FIG. 6A are top schematic views of various stages of manufacturing a display device 10A according to an embodiment of the disclosure. FIG. 1B, FIG. 2B, FIG. 3B, FIG. 4B, FIG. 5B, and FIG. 6B are respectively cross-sectional schematic views taken along a line A-A′ and a line B-B′ of FIG. 1A, FIG. 2A, FIG. 3A, FIG. 4A, FIG. 5A, and FIG. 6A. Please refer to FIG. 1A and FIG. 1B. A substrate 100 is provided. In some embodiments, the substrate 100 is, for example, a rigid substrate, and the material thereof may be glass, quartz, organic polymer, an opaque/reflective material (for example, conductive material, metal, wafer, ceramic, or other applicable materials), or other applicable materials. However, the disclosure is not limited thereto. In other embodiments, the substrate 100 may also be a flexible substrate or a stretchable substrate. For example, the materials of the flexible substrate and the stretchable substrate include polyimide (PI), polydimethylsiloxane (PDMS), polyethylene terephthalate (PET), polyethylene naphthalate (PEN), polyester (PES), polymethylmethacrylate (PMMA), polycarbonate (PC), polyurethane (PU), or other suitable materials. In some embodiments, the substrate 100 is a transparent substrate, which is applicable to a transparent display device.

The substrate 100 includes multiple chip placement areas CA and multiple pixel areas PA thereon. The chip placement area CA is a region for placing a microchip in a subsequent process. The pixel area PA is a region for disposing a light emitting element in a subsequent process. The pixel areas PA are respectively located around the corresponding chip placement areas CA. In some embodiments, the chip placement area CA and the pixel area PA are both disposed in a display area of a display device. Through disposing the chip placement area CA in the display area, the bezel size of the display device may be reduced.

Multiple first chip connection line structures 120A and multiple signal input structures 120B are located above the substrate 100. In the embodiment, a buffer layer 102 is located between the first chip connection line structure 120A and the substrate 100 and between the signal input structure 120B and the substrate 100. In some embodiments, other insulating layers and/or conductive layers are further included between the buffer layer 102 and the substrate 100. The first chip connection line structure 120A and the signal input structure 120B extend outward from the chip placement area CA. In some embodiments, the signal input structure 120B extends outward from the chip placement area CA to a signal source area (not shown). In some embodiments, the signal source area is disposed in a bezel area of the display device, but the disclosure is not limited thereto.

In some embodiments, the first chip connection line structure 120A includes a first chip bonding pad 122A, a first connection line 123A, and a first connection pad 124A. The first chip bonding pad 122A is disposed in the chip placement area CA. In some embodiments, the first connection pad 124A is located outside the chip placement area CA, and the first connection line 123A extends outward from the chip placement area CA to connect the first chip bonding pad 122A to the first connection pad 124A.

In some embodiments, a part of the first chip connection line structures 120A extends outward from a side (for example, the upper side in FIG. 1A) of the chip placement area CA to the outside of the chip placement area CA, and another part of the first chip connection line structures 120A extends outward from another side (for example, the lower side in FIG. 1A) of the chip placement area CA to the outside of the chip placement area CA.

The signal input structure 120B includes a second chip bonding pad 122B, a signal input line 123B, a second connection pad 124B, and a connection line 125B connecting the second chip bonding pad 122B and the second connection pad 124B. The second chip bonding pad 122B is disposed in the chip placement area CA and is electrically connected to the signal input line 123B through the connection line 125B and the second connection pad 124B. In some embodiments, the second connection pad 124B is located outside the chip placement area CA, and the signal input line 123B extends outward from the chip placement area CA to connect the second chip bonding pad 122B to the second connection pad 124B.

Please refer to FIG. 2A and FIG. 2B. First microchips 110A and 110B are respectively disposed in the chip placement area CA with active surfaces facing downward. In some embodiments, the first microchip 110A, 110B includes a driving circuit. The first microchips 110A and 110B each include multiple first chip pads 113. In some embodiments, the first chip pad 113 is located on a side of the first microchip 110A, 110B close to the substrate 100. In some embodiments, the first chip pad 113 includes a metal bump structure. For example, the first chip pad 113 includes gold, copper, tin, silver, lead, indium, other metal materials, or a combination of the above materials. The first chip pad 113 is disposed on the active surface of the first microchip 110A, 110B.

The first microchips 110A and 110B are respectively bonded to the corresponding first chip connection line structure 120A and signal input structure 120B through connection structures 115. Specifically, the first chip pads 113 of each of the first microchips 110A and 110B are bonded to the first chip bonding pad 122A of the corresponding first chip connection line structure 120A and the second chip bonding pad 122B of the corresponding signal input structure 120B through the connection structures 115. The connection structure 115 includes, for example, solder (for example, indium, tin, other suitable metal materials, or a combination of the above materials), conductive glue, or other conductive connection materials. In some embodiments, the signal input structure 120B is configured to provide an input signal to the first microchip 110A, 110B.

The first connection pad 124A of the first chip connection line structure 120A and the second connection pad 124B of the signal input structure 120B do not overlap with the first microchips 110A and 110B in a normal direction of a top surface of the substrate 100.

Please refer to FIG. 3A and FIG. 3B. The first microchips 110A and 110B are tested to confirm whether the first microchips 110A and 110B may operate normally. In the embodiment, the first microchip 110A cannot operate normally, but the first microchip 110B may operate normally. For example, the first microchip 110A may be offset when placed on the substrate 100 or may have internal defects, causing the first microchip 110A to be unable to output and/or receive expected signals. The first microchip 110A may also be referred to as a failed microchip. In the embodiment, the failed microchip (that is, the first microchip 110A) is located in the chip placement area CA. The failed microchip is at least partially connected to the first chip connection line structure 120A and the signal input structure 120B. In some embodiments, since the failed microchip is offset when placed, a part of the first chip pads 113 of the failed microchip is not bonded to the first chip connection line structure 120A and the signal input structure 120B.

In some embodiments, after confirming that the first microchip 110A is the failed microchip, the first chip connection line structure 120A corresponding to the first microchip 110A is cut through a cutting process (for example, laser cutting or other suitable cutting manners) to cut off the first connection line 123A between the first chip bonding pad 122A and the first connection pad 124A, which may ensure that the first microchip 110A cannot output signals to a light emitting element that will be subsequently transferred to above the substrate 100 through the first chip connection line structure 120A. On the other hand, the connection line 125B corresponding to the first microchip 110A may also be cut to ensure that the signal input line 123B does not transmit signals to the first microchip 110A.

In some embodiments, at least one of the first chip connection line structures 120A is cut to have a first part 120A-1 (such as including the first chip bonding pad 122A and a part of the first connection line 123A connected to the first chip bonding pad 122A) and a second part 120A-2 (such as including the first connection pad 124A and a part of the first connection line 123A connected to the first connection pad 124A) separated from each other. In some embodiments, the failed microchip (that is, the first microchip 110A) is electrically connected to the first part 120A-1.

Please refer to FIG. 4A and FIG. 4B. A first insulating layer 140 is formed above the substrate 100. The first insulating layer 140 is located on the first chip connection line structure 120A and the signal input structure 120B, and the first chip connection line structure 120A and the signal input structure 120B are located between the first insulating layer 140 and the substrate 100. The first insulating layer 140 laterally surrounds the first microchips 110A and 110B.

In some embodiments, the material of the first insulating layer 140 includes photoresist (for example, positive photoresist or negative photoresist), polyimide (PI), an acrylic material, or other insulating materials. In some embodiments, the thickness of the first insulating layer 140 is 5 micrometers to 25 micrometers.

The first insulating layer 140 has multiple first openings O1 and multiple second openings O2. The first opening O1 exposes the first connection pad 124A located at the bottom thereof, and the second opening O2 exposes the second connection pad 124B located at the bottom thereof. In some embodiments, depths H1 of the first opening O1 and the second opening O2 are 5 micrometers to 25 micrometers, and widths W1 are 5 micrometers to 35 micrometers.

Please refer to FIG. 5A and FIG. 5B. Multiple second chip connection line structures 130A, multiple bridging structures 130B, multiple first light emitting diode bonding pads 152, and multiple second light emitting diode bonding pads 154 are formed on the first insulating layer 140. At least a part of the second chip connection line structure 130A is electrically connected to the first chip connection line structure 120A. For example, the second chip connection line structures 130A are respectively filled into the first openings O1 of the first insulating layer 140 to be connected to the corresponding first chip connection line structures 120A. The bridging structures 130B are respectively filled into the second openings O2 of the first insulating layer 140 to be connected to the signal input structures 120B.

In some embodiments, the second chip connection line structure 130A includes a first repair pad 132A, a second connection line 133A, a first conductive filling portion 134A, and a signal output line 135A. The first repair pad 132A is disposed in the chip placement area CA. In some embodiments, the first conductive filling portion 134A is located outside the chip placement area CA, is filled into the first opening O1 of the first insulating layer 140, and is connected to the corresponding first connection pad 124A through the first opening O1. The second connection line 133A extends outward from the chip placement area CA to connect the first repair pad 132A to the first conductive filling portion 134A. The signal output line 135A extends into the pixel area PA and is connected to the first light emitting diode bonding pad 152 in the pixel area PA. In some embodiments, each pixel area PA further includes one or more second light emitting diode bonding pads 154. In some embodiments, the second light emitting diode bonding pads 154 are connected to each other and are electrically connected to a common voltage.

In some embodiments, the bridging structure 130B includes a second repair pad 132B, a third connection line 133B, and a second conductive filling portion 134B. The second repair pad 132B is disposed in the chip placement area CA. In some embodiments, the second conductive filling portion 134B is located outside the chip placement area CA, is filled into the second opening O2 of the first insulating layer 140, and is connected to the corresponding second connection pad 124B through the second opening O2. The third connection line 133B extends outward from the chip placement area CA to connect the second repair pad 132B to the second conductive filling portion 134B.

Please refer to FIG. 6A and FIG. 6B. A repair microchip 210 is disposed in the chip placement area CA corresponding to the failed microchip. In the embodiment, the repair microchip 210 is located in the chip placement area CA and at least partially overlaps with the failed microchip (that is, the first microchip 110A). The chip placement area CA corresponding to the first microchip 110B that may operate normally does not need to be provided with the repair microchip 210. In the embodiment, the repair microchip 210 is disposed in the chip placement area CA with an active surface facing downward. The repair microchip 210 includes multiple second chip pads 213. In some embodiments, the second chip pad 213 is located on a side of the repair microchip 210 close to the substrate 100. In some embodiments, the repair microchip 210 has the same structural design as the first microchips 110A and 110B, so there is no need to redesign the microchip for the repair process. For example, the relative positions of the second chip pads 213 on the repair microchip 210 are equal to the relative positions of the first chip pads 113 of each of the first microchips 110A and 110B. In some embodiments, the second chip pad 213 includes a metal bump structure. For example, the second chip pad 213 includes gold, copper, tin, silver, lead, indium, other metal materials or a combination of the above materials.

The repair microchip 210 is located above the first insulating layer 140 and is bonded to the corresponding second chip connection line structure 130A and bridging structure 130B through connection structures 215. Specifically, the second chip pad 213 of the repair microchip 210 is connected to the first repair pad 132A of the corresponding second chip connection line structure 130A and the second repair pad 132B of the corresponding bridging structure 130B through the connection structures 215. The connection structure 215 includes, for example, solder (for example, indium, tin, other suitable metal materials, or a combination of the above materials), conductive glue, or other conductive connection materials. The repair microchip 210 is electrically connected to the signal input structure 120B by the bridging structure 130B corresponding to the failed microchip. For example, the second chip connection line structure 130A is configured to provide data signals from the microchip to light emitting elements 310, 320, and 330, and the signal input structure 120B is configured to provide input signals to the microchip.

In some embodiments, after the repair microchip 210 is bonded to the corresponding second chip connection line structure 130A and bridging structure 130B, and before the light emitting elements 310, 320, and 330 are disposed in the pixel area PA, the repair microchip 210 is tested to confirm whether the repair microchip 210 may operate normally.

The light emitting elements 310, 320, and 330 are respectively disposed in the pixel area PA. The light emitting elements 310, 320, and 330 are located on the first insulating layer 140, and electrodes E of each of the light emitting elements 310, 320, and 330 are bonded to the first light emitting diode bonding pad 152 and the second light emitting diode bonding pad 154 through connection structures S. The connection structure S includes, for example, solder (for example, indium, tin, other suitable metal materials, or a combination of the above materials), conductive glue, or other conductive connection materials. In some embodiments, the light emitting elements 310, 320, and 330 include micro light emitting diodes. For example, the light emitting elements 310, 320, and 330 are respectively a red micro light emitting diode, a green micro light emitting diode, and a blue micro light emitting diode.

In some embodiments, the connection structures 215 and S are first formed above the substrate 100 through evaporation or other suitable methods, and the repair microchip 210 and the light emitting elements 310, 320, and 330 are then bonded to the connection structures 215 and S, but the disclosure is not limited thereto. In other embodiments, the connection structures 215 and S are respectively formed on the repair microchip 210 and the light emitting elements 310, 320, and 330, and the repair microchip 210 and the light emitting elements 310, 320, and 330 are then disposed above the substrate 100.

The repair microchip 210 is electrically connected to the light emitting elements 310, 320, and 330 by the second chip connection line structure 130A corresponding to the failed microchip (that is, the first microchip 110A). The repair microchip 210 outputs data signals to the corresponding light emitting elements 310, 320, and 330 through the corresponding second chip connection line structure 130A. In some embodiments, the repair microchip 210 is electrically connected to a part (for example, the second part 120A-2) of the first chip connection line structure 120A through the second chip connection line structure 130A. In the embodiment, at least one of the second chip connection line structures 130A corresponding to the first microchip 110A (that is, the failed microchip) is electrically connected to the second part 120A-2 of the first chip connection line structure 120A and is electrically independent of the first part 120A-1 of the corresponding first chip connection line structure 120A. Since the first chip connection line structure 120A corresponding to the first microchip 110A is cut off, the first microchip 110A cannot output data signals to the corresponding light emitting elements 310, 320, and 330. In addition, since the first chip connection line structure 120A corresponding to the first microchip 110B is not cut off, the first microchip 110B may output data signals to the corresponding light emitting elements 310, 320, and 330 through the first chip connection line structure 120A and the second chip connection line structure 130A.

Based on the above, in the display device 10A, the repair microchip 210 may replace the failed first microchip 110A to output data signals to the corresponding light emitting elements 310, 320, and 330, so as to improve the yield of the display device 10A.

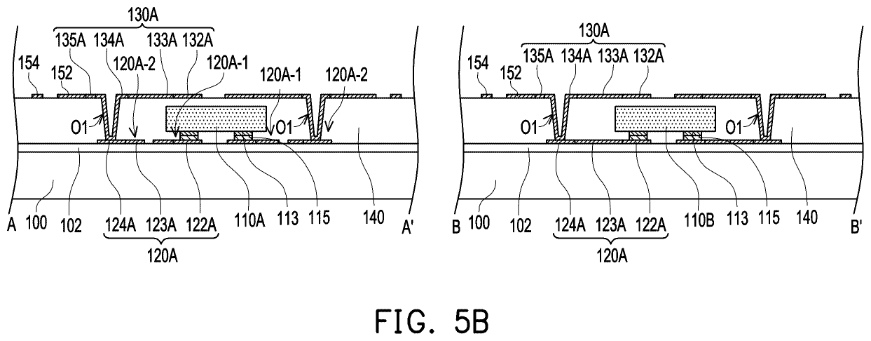

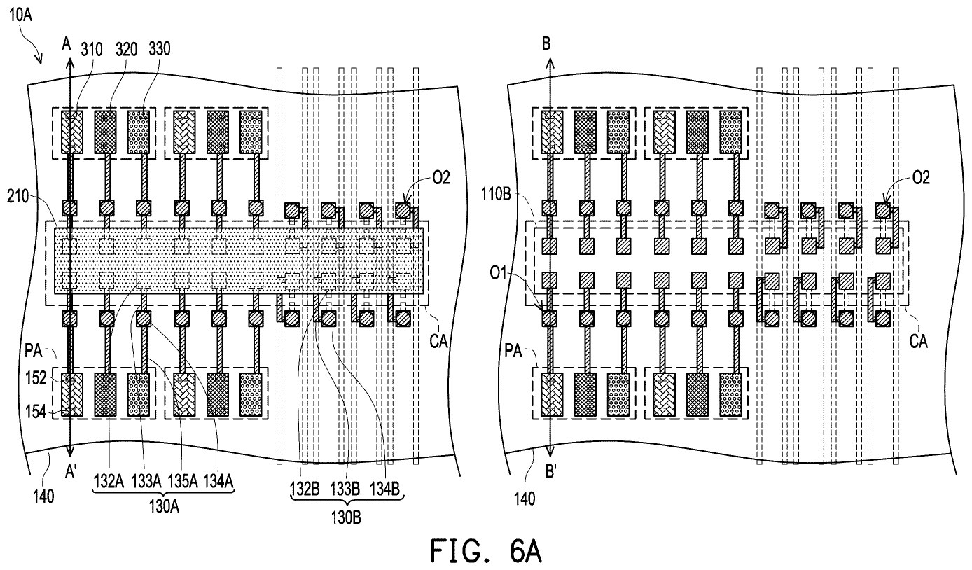

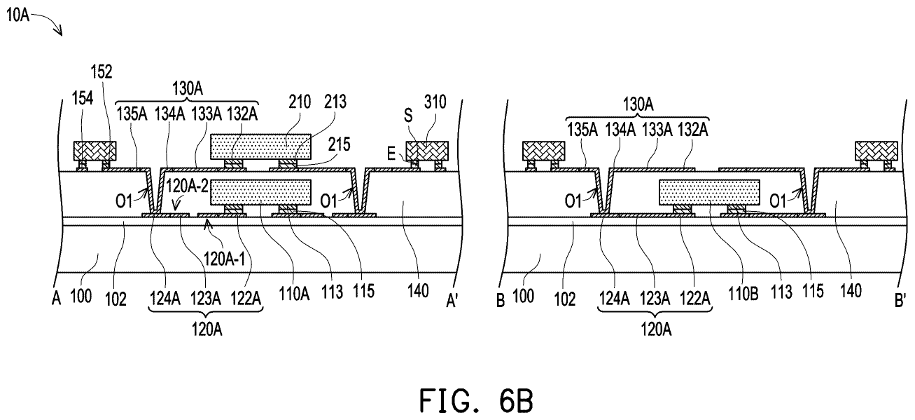

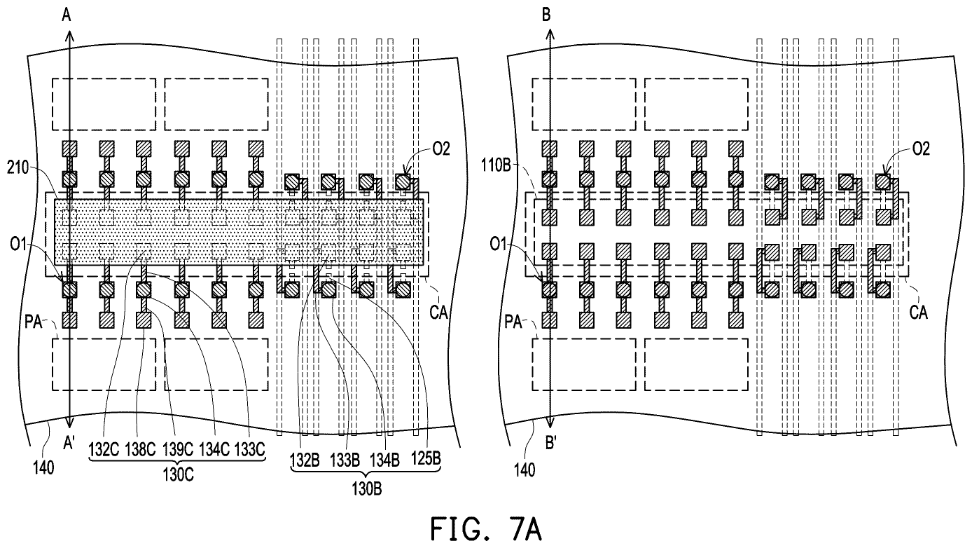

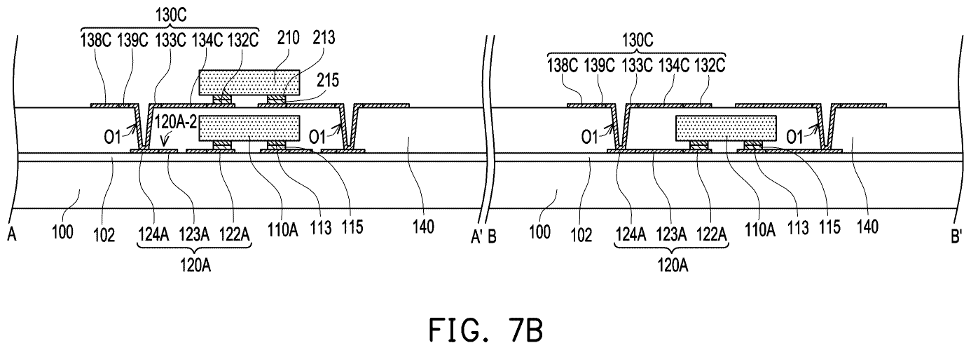

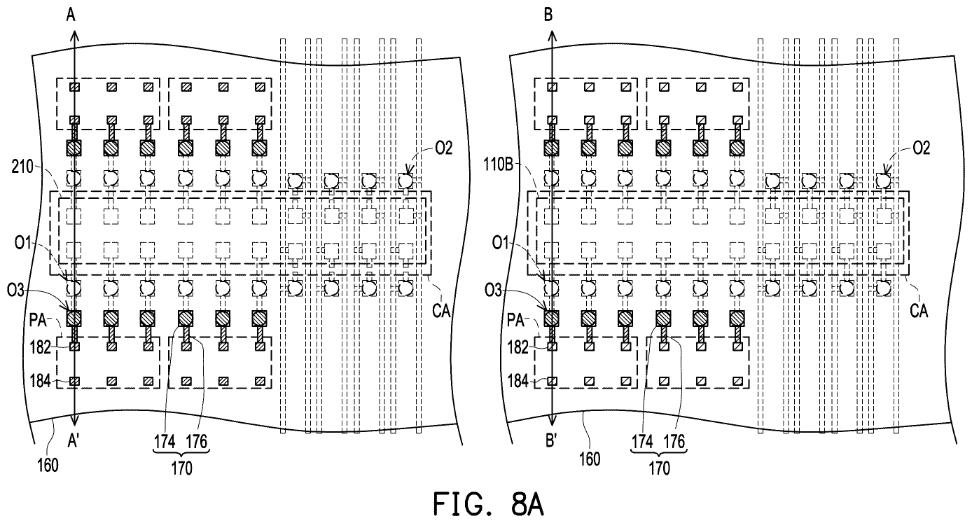

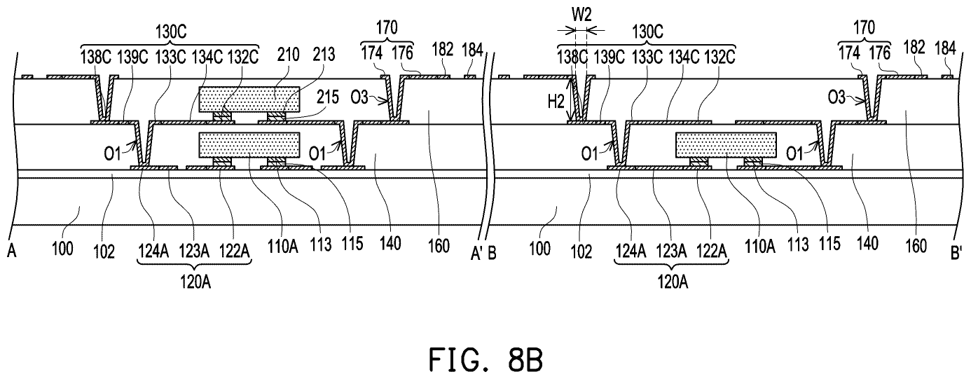

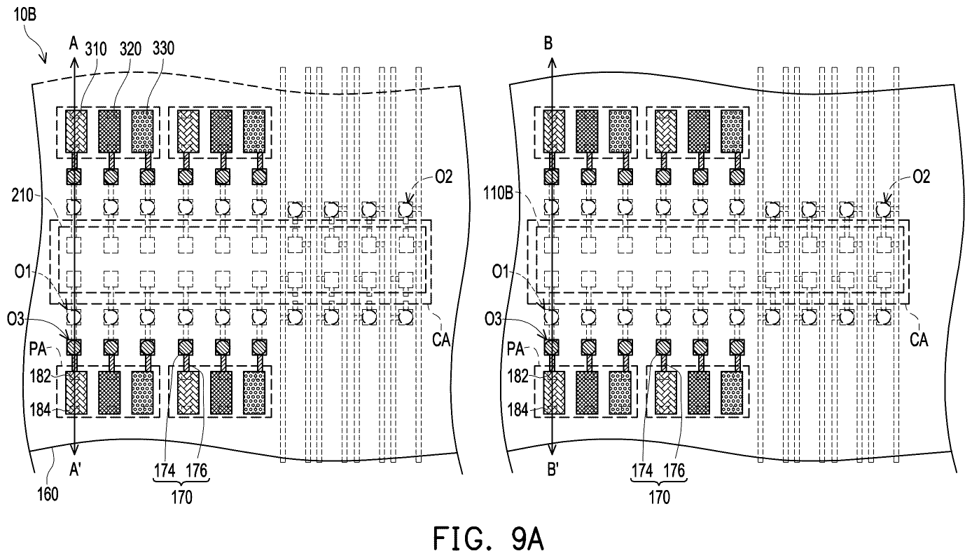

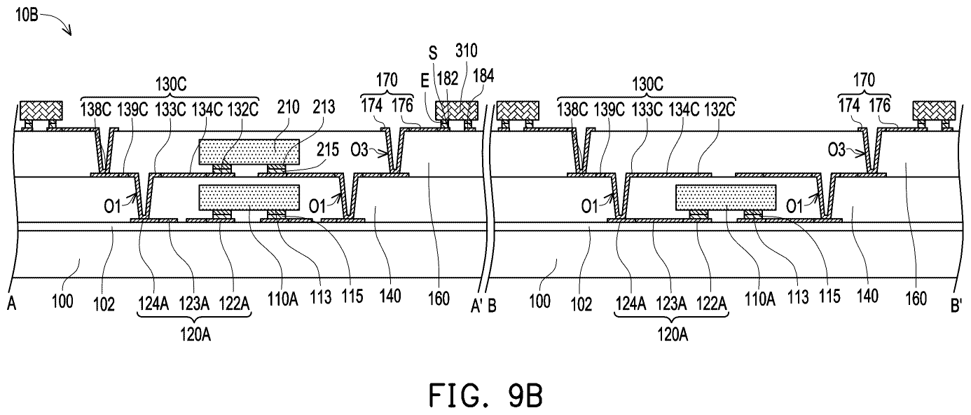

FIG. 7A, FIG. 8A, and FIG. 9A are top schematic views of various stages of manufacturing a display device 10B according to an embodiment of the disclosure. FIG. 7B, FIG. 8B, and FIG. 9B are respectively cross-sectional schematic views taken along a line A-A′ and a line B-B′ of FIG. 7A, FIG. 8A, and FIG. 9A.

It must be noted here that the embodiment of FIG. 7A to FIG. 9B continues to use the reference numerals and some content of the embodiment of FIG. 1A to FIG. 6B, wherein the same or similar reference numerals are adopted to represent the same or similar elements, and the description of the same technical contents is omitted. Reference may be made to the foregoing embodiment for the description of the omitted part, which will not be repeated here.

Please refer to FIG. 7A and FIG. 7B. Following the steps of FIG. 4A and FIG. 4B, multiple second chip connection line structures 130C and multiple bridging structures 130B are formed on the first insulating layer 140. At least a part of the second chip connection line structures 130C is electrically connected to the first chip connection line structure 120A. For example, the second chip connection line structures 130C are respectively filled into the first openings O1 to be connected to the corresponding first chip connection line structures 120A. The bridging structures 130B are respectively filled into the second openings O2 to be connected to the signal input structures 120B.

In some embodiments, the second chip connection line structure 130C includes a first repair pad 132C, a second connection line 133C, a first conductive filling portion 134C, a third connection pad 138C, and a signal transmission line 139C. The first repair pad 132C is disposed in the chip placement area CA. In some embodiments, the first conductive filling portion 134C is located outside the chip placement area CA, is filled into the first opening O1, and is connected to the corresponding first connection pad 124A through the first opening O1. The second connection line 133C extends outward from the chip placement area CA to connect the first repair pad 132C to the first conductive filling portion 134C. The signal transmission line 139C is connected to the first conductive filling portion 134C and the third connection pad 138C.

The repair microchip 210 is placed in the chip placement area CA corresponding to the failed microchip. The chip placement area CA corresponding to the first microchip 110B that may operate normally does not need to be provided with the repair microchip 210. The repair microchip 210 is located above the first insulating layer 140 and is bonded to the corresponding second chip connection line structure 130C and bridging structure 130B through the connection structures 215. Specifically, the second chip pad 213 of the repair microchip 210 is bonded to the first repair pad 132C of the corresponding second chip connection line structure 130C and the second repair pad 132B of the corresponding bridging structure 130B through the connection structures 215. The repair microchip 210 is electrically connected to the signal input structure 120B by the bridging structure 130B corresponding to the failed microchip. For example, the signal input structure 120B is configured to provide input signals to the microchip.

In the embodiment, the repair microchip 210 is located in the chip placement area CA and at least partially overlaps with the failed microchip (that is, the first microchip 110A). In some embodiments, the repair microchip 210 is electrically connected to a part (for example, the second part 120A-2) of the first chip connection line structure 120A through the second chip connection line structure 130C.

Please refer to FIG. 8A and FIG. 8B. A second insulating layer 160 is formed on the first insulating layer 140, the second chip connection line structure 130C, and the bridging structure 130B. The second chip connection line structure 130C and the bridging structure 130B are located between the first insulating layer 140 and the second insulating layer 160. The second insulating layer 160 laterally surrounds the repair microchip 210.

Multiple signal output lines 170, multiple first light emitting diode bonding pads 182, and multiple second light emitting diode bonding pads 184 are formed above the second insulating layer 160. The signal output line 170 is electrically connected to the second chip connection line structure 130C. For example, the signal output lines 170 are respectively filled into third openings O3 in the second insulating layer 160 to be connected to the corresponding second chip connection line structures 130C. In some embodiments, a depth H2 of the third opening O3 is 5 micrometers to 25 micrometers, and a width W2 is 5 micrometers to 35 micrometers.

In some embodiments, the signal output line 170 includes a third conductive filling portion 174 and a signal output line 176. The third conductive filling portion 174 is filled into the third opening O3 and is connected to the corresponding third connection pad 138C through the third opening O3. The signal output line 176 extends from the third conductive filling portion 174 into the pixel area PA and is connected to the first light emitting diode bonding pad 182 in the pixel area PA. In some embodiments, each pixel area PA further includes one or more second light emitting diode bonding pads 184. In some embodiments, the second light emitting diode bonding pads 184 are connected to each other and are electrically connected to a common voltage.

Please refer to FIG. 9A and FIG. 9B. The light emitting elements 310, 320, and 330 are respectively disposed in the pixel area PA. The light emitting elements 310, 320, and 330 are located on the second insulating layer 160, and the electrodes E of each of the light emitting elements 310, 320, and 330 are bonded to the first light emitting diode bonding pad 182 and the second light emitting diode bonding pad 184 through the connection structures S.

The light emitting elements 310, 320, and 330 are respectively electrically connected to the signal output structure 170. The repair microchip 210 is electrically connected to the signal output structure 170 through the second chip connection line structure 130C, thereby providing data signals to the light emitting elements 310, 320, and 330. Since the first chip connection line structure 120A corresponding to the first microchip 110A is cut off, the first microchip 110A cannot transmit data signals to the corresponding light emitting elements 310, 320, and 330. In addition, since the first chip connection line structure 120A corresponding to the first microchip 110B is not cut off, the first microchip 110B may transmit data signals to the corresponding light emitting elements 310, 320, and 330 through the first chip connection line structure 120A, the second chip connection line structure 130C, and the signal output structure 170.

Based on the above, in the display device 10B, the repair microchip 210 may replace the failed first microchip 110A to output data signals to the corresponding light emitting elements 310, 320, and 330, so as to improve the yield of the display device 10B.

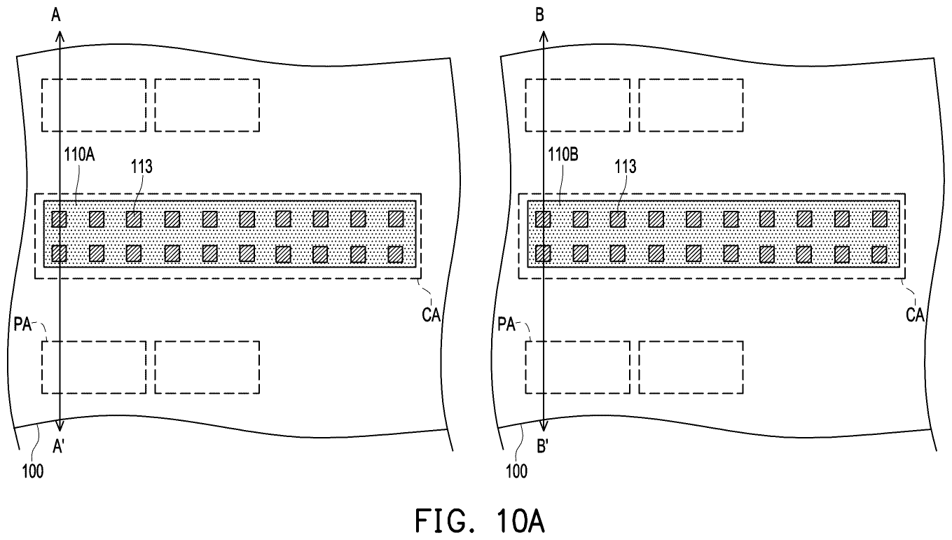

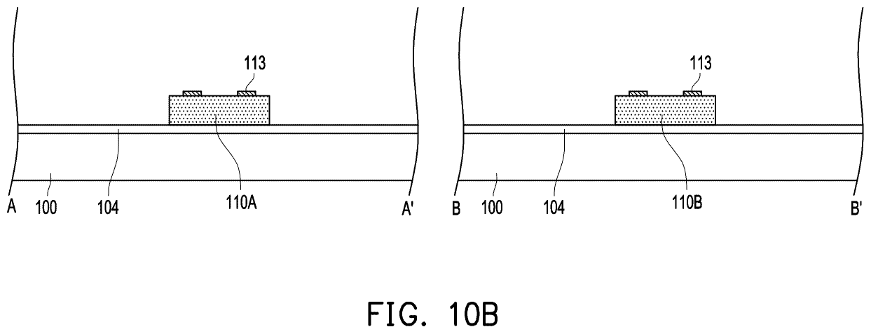

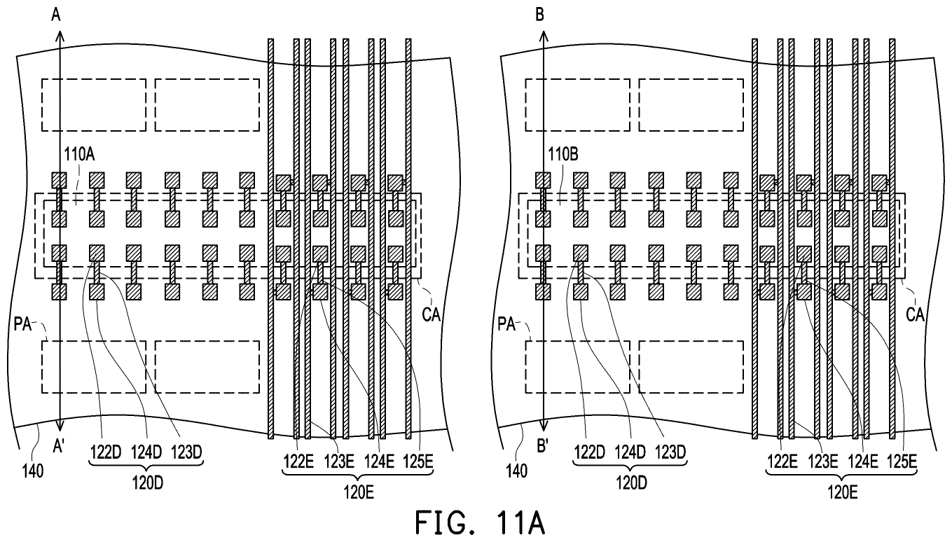

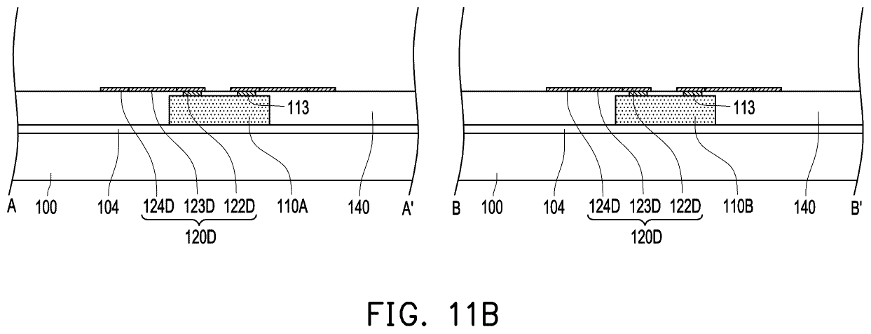

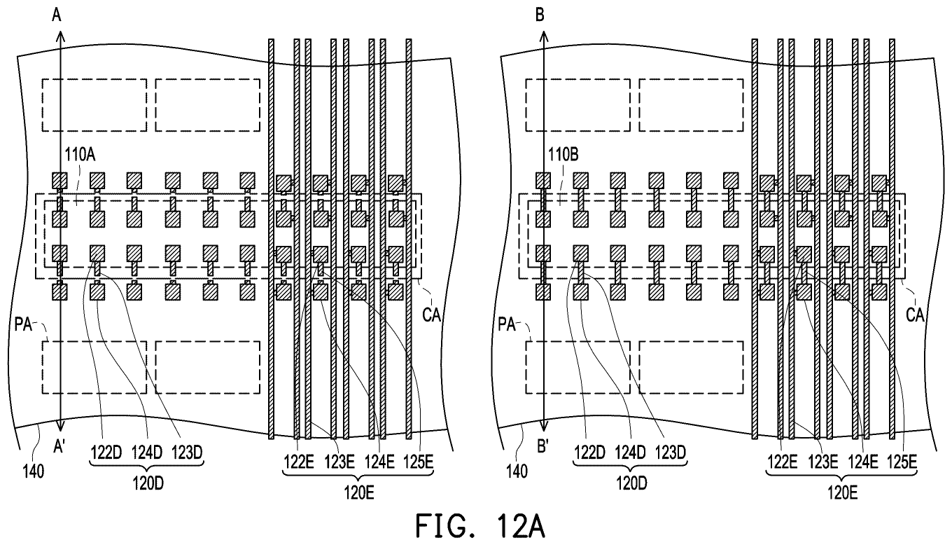

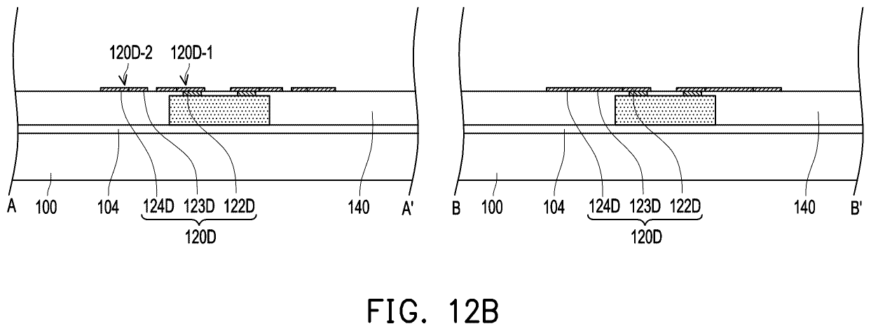

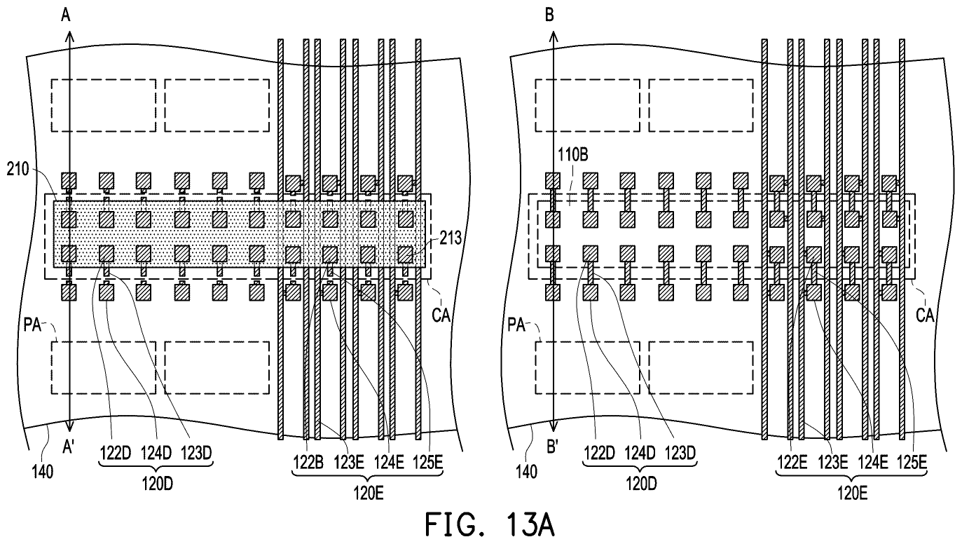

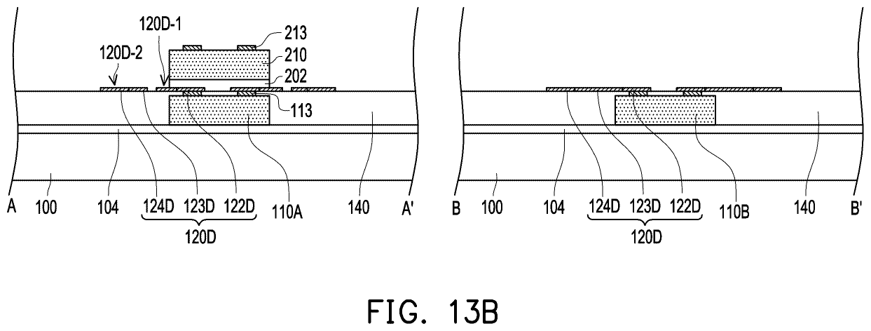

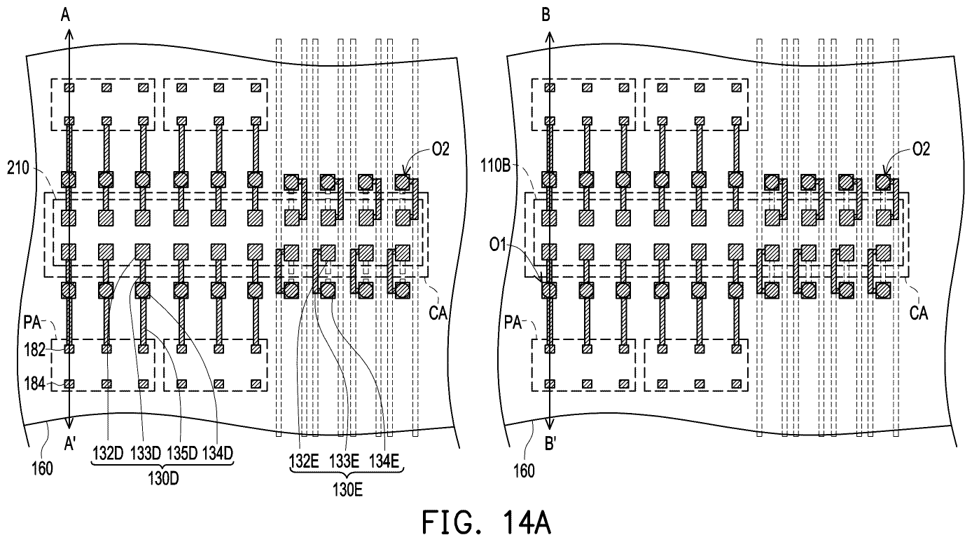

FIG. 10A, FIG. 11A, FIG. 12A, FIG. 13A, FIG. 14A, and FIG. 15A are top schematic views of various stages of manufacturing a display device 10C according to an embodiment of the disclosure. FIG. 10B, FIG. 11B, FIG. 12B, FIG. 13B, FIG. 14B, and FIG. 15B are respectively cross-sectional schematic views taken along a line A-A′ and a line B-B′ of FIG. 10A, FIG. 11A, FIG. 12A, FIG. 13A, FIG. 14A, and FIG. 15A.

Please refer to FIG. 10A and FIG. 10B. The first microchips 110A and 110B are disposed on the substrate 100. For example, the first microchips 110A and 110B are attached to the substrate 100 through an adhesion layer 104. The first microchips 110A and 110B are respectively disposed in different chip placement areas CA. In some embodiments, after the first microchips 110A and 110B are placed in the chip placement areas CA, automated optical inspection (AOI) is performed to detect the positions of the first microchips 110A and 110B.

In the embodiment, the first microchips 110A and 110B are attached to the top surface of the substrate 100 through the adhesion layer 104, but the disclosure is not limited thereto. In other embodiments, the top surface of the substrate 100 includes a circuit structure (not shown), and the first microchips 110A and 110B are attached to the circuit structure through the adhesion layer 104.

In the embodiment, the entire adhesion layer 104 is formed above the substrate 100, and a part of the adhesion layer 104 does not overlap with the first microchips 110A and 110B, but the disclosure is not limited thereto. In other embodiments, multiple separated adhesion layers 104 respectively attach the first microchips 110A and 110B to the substrate 100.

In the embodiment, the first microchips 110A and 110B are both disposed in the chip placement areas CA with the active surfaces facing upward. The first microchips 110A and 110B each include multiple first chip pads 113. The first chip pad 113 is disposed on the active surface and is located on a side of the first microchip 110A, 110B facing away from the substrate 100.

Please refer to FIG. 11A and FIG. 11B. The first insulating layer 140 is formed above the substrate 100. The first insulating layer 140 laterally surrounds the first microchips 110A and 110B. The first chip pad 113 of the first microchip 110A, 110B is exposed by the first insulating layer 140.

Multiple first chip connection line structures 120D and multiple signal input structures 120E are formed above the first insulating layer 140. The first chip connection line structure 120D extends outward from the chip placement area CA, and the signal input structure 120E extends from the chip placement area CA to the signal source area (not shown). In some embodiments, the signal source area is disposed in the bezel area of the display device, but the disclosure is not limited thereto.

In some embodiments, the first chip connection line structure 120D includes a first chip bonding pad 122D, a first connection line 123D, and a first connection pad 124D. The first chip bonding pad 122D is disposed in the chip placement area CA. In some embodiments, the first connection pad 124D is located outside the chip placement area CA, and the first connection line 123D extends outward from the chip placement area CA to connect the first chip bonding pad 122D to the first connection pad 124D.

In some embodiments, a part of the first chip connection line structures 120D extends outward from a side (for example, the upper side in FIG. 11A) of the chip placement area CA to the outside of the chip placement area CA, and another part of the first chip connection line structures 120D extends outward from another side (for example, the lower side in FIG. 11A) of the chip placement area CA to the outside of the chip placement area CA.

The signal input structure 120E includes a second chip bonding pad 122E, a signal input line 123E, a second connection pad 124E, and a connection line 125E connecting the second chip bonding pad 122E and the second connection pad 124E. The second chip bonding pad 122E is disposed in the chip placement area CA and is electrically connected to the signal input line 123E through the connection line 125E and the second connection pad 124B. In some embodiments, the second connection pad 124E is located outside the chip placement area CA, and the signal input line 123E extends outward from the chip placement area CA to connect the second chip bonding pad 122E to the second connection pad 124E.

In some embodiments, the first chip bonding pad 122D and the second chip bonding pad 122E are directly formed on the first chip pads 113 of the first microchip 110A, 110B and directly contact at least a part of the first chip pads 113 of the first microchip 110A, 110B. In some embodiments, the first microchip 110A is offset when placed, causing a part or all of the first chip pads 113 of the first microchip 110A to not be aligned with the first chip bonding pad 122D and/or the second chip bonding pad 122E.

Please refer to FIG. 12A and FIG. 12B. The first microchips 110A and 110B are tested to confirm whether the first microchips 110A and 110B may operate normally. For example, the first microchips 110A and 110B are tested through a full contact test. In the embodiment, the first microchip 110A cannot operate normally, but the first microchip 110B may operate normally. For example, the first microchip 110A may be offset when placed on the substrate 100 or may have internal defects, causing the first microchip 110A to be unable to output and/or receive expected signals. The first microchip 110A may also be referred to as the failed microchip. In the embodiment, the failed microchip (that is, the first microchip 110A) is located in the chip placement area CA. The failed microchip is at least partially connected to the first chip connection line structure 120D and the signal input structure 120E. In some embodiments, since the failed microchip is offset when placed, a part of the first chip pads 113 of the failed microchip is not bonded to the first chip connection line structure 120D and the signal input structure 120E.

In some embodiments, after confirming that the first microchip 110A is the failed microchip, the first chip connection line structure 120D corresponding to the first microchip 110A is cut through a cutting process (for example, laser cutting or other suitable cutting manners) to cut off the first connection line 123D between the first chip bonding pad 122D and the first connection pad 124D, which may ensure that the first microchip 110A no longer outputs signals to the light emitting element that will be subsequently transferred to above the substrate 100 through the first chip connection line structure 120D. On the other hand, the connection line 125E corresponding to the first microchip 110A may be cut to ensure that the signal input line 123E does not transmit signals to the first microchip 110A.

In some embodiments, at least one of the first chip connection line structures 120D is cut to have a first part 120D-1 (such as including the first chip bonding pad 122D and a part of the first connection line 123D connected to the first chip bonding pad 122D) and a second part 120D-2 (such as including the first connection pad 124D and a part of the first connection line 123D connected to the first connection pad 124D) separated from each other. The failed microchip (that is, the first microchip 110A) is electrically connected to the first part 120D-1.

Please refer to FIG. 13A and FIG. 13B. The repair microchip 210 is disposed in the chip placement area CA corresponding to the failed microchip. The chip placement area CA corresponding to the first microchip 110B that may operate normally does not need to be provided with the repair microchip 210. For example, the repair microchip 210 is placed in the chip placement area CA through pick and place (PNP). In the embodiment, the repair microchip 210 is placed in the chip placement area CA with the active surface facing upward. The repair microchip 210 includes the second chip pads 213. In some embodiments, the second chip pad 213 is located on a side of the repair microchip 210 facing away from the substrate 100. In some embodiments, the repair microchip 210 has the same structural design as the first microchips 110A and 110B, so there is no need to redesign the microchip for the repair process. For example, the relative positions of the second chip pads 213 on the repair microchip 210 are equal to the relative positions of the first chip pads 113 of each of the first microchips 110A and 110B.

In some embodiments, the repair microchip 210 is adhered to the first insulating layer 140 through an adhesion layer 202. In some embodiments, the repair microchip 210 is adhered to the first part 120D-1 in the first chip connection line structure 120D through the adhesion layer 202. A part (for example, the first part 120D-1) of the first chip connection line structure 120D is located between the repair microchip 210 and the failed microchip (that is, the first microchip 110A).

Please refer to FIG. 14A and FIG. 14B. The second insulating layer 160 is formed on the first insulating layer 140, the first chip connection line structure 120D, and the signal input structure 120E. The first chip connection line structure 120D and the signal input structure 120E are located between the first insulating layer 140 and the second insulating layer 160. The second insulating layer 160 laterally surrounds the repair microchip 210.

The second insulating layer 160 has the first openings O1 and the second openings O2. The first opening O1 exposes the first connection pad 124D located at the bottom thereof, and the second opening O2 exposes the second connection pad 124E located at the bottom thereof.

Multiple second chip connection line structures 130D, multiple bridging structures 130E, the first light emitting diode bonding pads 182, and the second light emitting diode bonding pads 184 are formed on the second insulating layer 160. At least a part of the second chip connection line structures 130D is electrically connected to the first chip connection line structures 120D. For example, the second chip connection line structures 130D are respectively filled into the first openings O1 of the second insulating layer 160 to be connected to the corresponding first chip connection line structures 120D. The bridging structures 130E are respectively filled into the second openings O2 of the second insulating layer 160 to be connected to the signal input structures 120E.

In some embodiments, the second chip connection line structure 130D includes a first repair pad 132D, a second connection line 133D, a first conductive filling portion 134D, and a signal output line 135D. The first repair pad 132D is disposed in the chip placement area CA. In some embodiments, the first repair pad 132D is directly formed on the second chip pad 213 of the repair microchip 210. In some embodiments, the first conductive filling portion 134D is located outside the chip placement area CA, is filled into the first opening O1 of the second insulating layer 160, and is connected to the corresponding first connection pad 124D through the first opening O1. The second connection line 133D extends outward from the chip placement area CA to connect the first repair pad 132D to the first conductive filling portion 134D. The signal output line 135D extends into the pixel area PA and is connected to the first light emitting diode bonding pad 182 in the pixel area PA. In some embodiments, each pixel area PA further includes one or more second light emitting diode bonding pads 184. In some embodiments, the second light emitting diode bonding pads 184 are connected to each other and are electrically connected to a common voltage.

In some embodiments, the bridging structure 130E includes a second repair pad 132E, a third connection line 133E, and a second conductive filling portion 134E. The second repair pad 132E is disposed in the chip placement area CA. In some embodiments, the second repair pad 132E is directly formed on the second chip pad 213 of the repair microchip 210. In some embodiments, the second conductive filling portion 134E is located outside the chip placement area CA, is filled into the second opening O2 of the second insulating layer 160, and is connected to the corresponding second connection pad 124E through the second opening O2. The third connection line 133E extends outward from the chip placement area CA to connect the second repair pad 132E to the second conductive filling portion 134E.

Please refer to FIG. 15A and FIG. 15B. The light emitting elements 310, 320, and 330 are respectively disposed in the pixel area PA. The light emitting elements 310, 320, and 330 are located on the second insulating layer 160, and the electrodes E of each of the light emitting elements 310, 320, and 330 are bonded to the first light emitting diode bonding pad 182 and the second light emitting diode bonding pad 184 through the connection structures S.

In some embodiments, the connection structures S are first formed above the substrate 100 through evaporation or other suitable methods, and the light emitting elements 310, 320, and 330 are then bonded to the connection structures S, but the disclosure is not limited thereto. In other embodiments, the connection structures S are respectively formed on the light emitting elements 310, 320, and 330, and the light emitting elements 310, 320, and 330 are then disposed above the substrate 100.

The repair microchip 210 is electrically connected to the corresponding light emitting elements 310, 320, and 330 through the corresponding second chip connection line structures 130D. In the embodiment, at least one of the second chip connection line structures 130D corresponding to the first microchip 110A (that is, the failed microchip) is electrically connected to the second part 120D-2 of the first chip connection line structure 120D and is electrically independent of the first part 120D-1 of the corresponding first chip connection line structure 120D. Since the first chip connection line structure 120D corresponding to the first microchip 110A is cut off, the first microchip 110A cannot transmit data signals to the corresponding light emitting elements 310, 320, and 330. In addition, since the first chip connection line structure 120D corresponding to the first microchip 110B is not cut off, the first microchip 110B may transmit data signals to the corresponding light emitting elements 310, 320, and 330 through the first chip connection line structure 120D and the second chip connection line structure 130D.

Based on the above, in the display device 10C, the repair microchip 210 may replace a failed first microchip 110C to output data signals to the corresponding light emitting elements 310, 320, and 330, so as to improve the yield of the display device 10C.

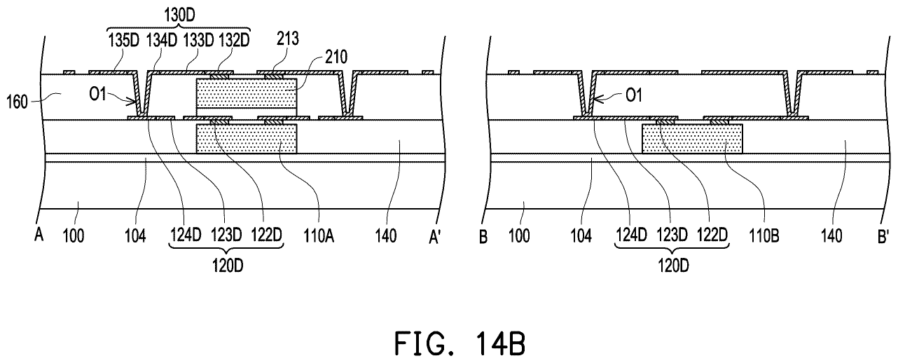

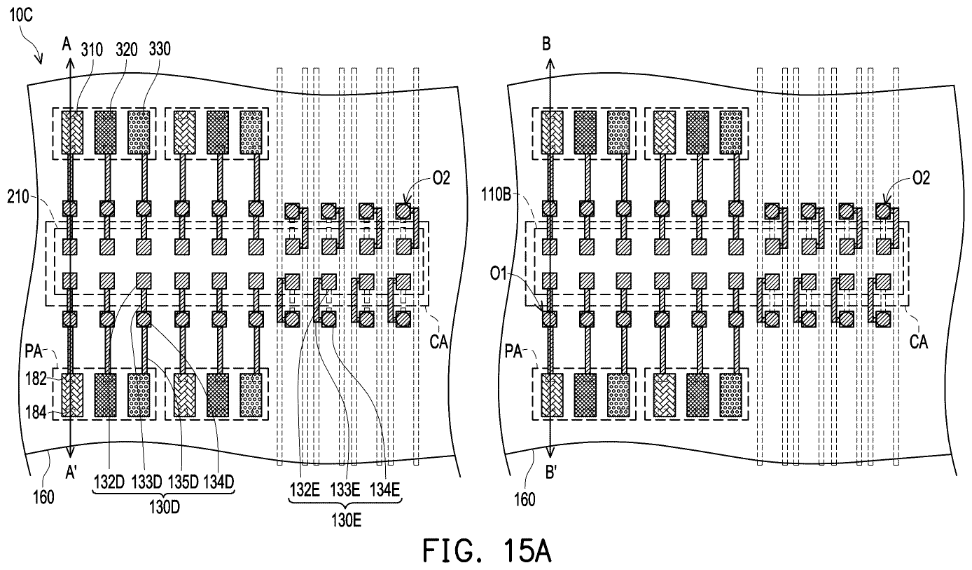

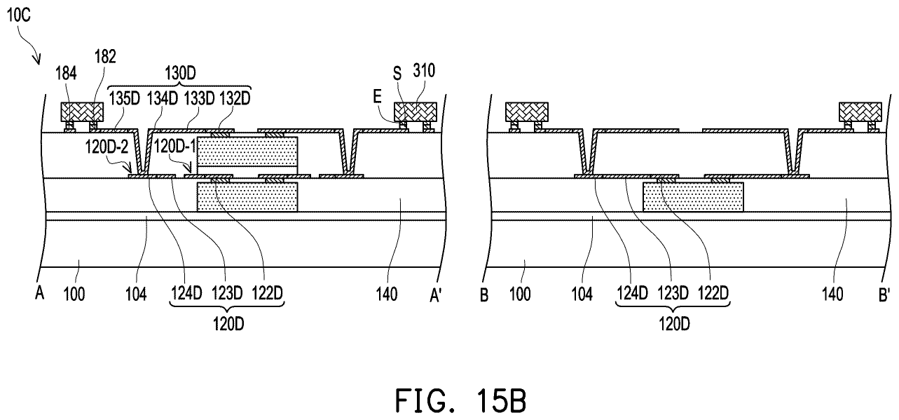

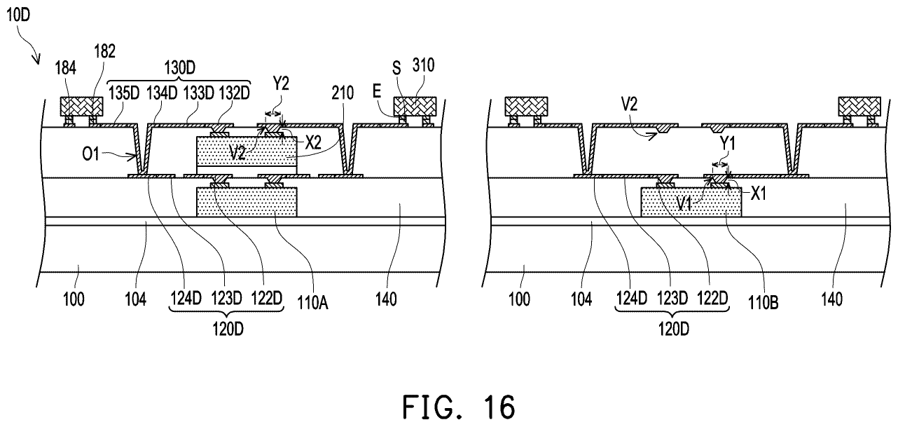

FIG. 16 is a cross-sectional schematic view of manufacturing a display device 10D according to an embodiment of the disclosure. It must be noted here that the embodiment of FIG. 16 continues to use the reference numerals and some content of the embodiment of FIG. 10A to FIG. 15B, wherein the same or similar reference numerals are adopted to represent the same or similar elements, and the description of the same technical contents is omitted. Reference may be made to the foregoing embodiment for the description of the omitted part, which will not be repeated here. Please refer to FIG. 16. In the embodiment, a top surface of the first insulating layer 140 is higher than a top surface of the first chip pad 113. The first chip connection line structure 120D is filled into an opening V1 of the first insulating layer 140 located on the first chip pad 113 to be connected to the first chip pad 113. In some embodiments, a depth X1 of the opening V1 is 0.1 micrometer to 20 micrometers, and a width Y1 is 3 micrometers to 100 micrometers.

In addition, in the embodiment, a top surface of the second insulating layer 160 is higher than a top surface of the second chip pad 213. The second chip connection line structure 130D is filled into an opening V2 of the second insulating layer 160 located on the second chip pad 113 to be connected to the second chip pad 213. In some embodiments, a depth X2 of the opening 5 V2 is 0.1 micrometers to 20 micrometers, and a width Y2 is 3 micrometers to 100 micrometers.

In some embodiments, in addition to the opening V2 at the position where the repair microchip 210 is disposed, a region corresponding to the first microchip 110B not including the repair microchip 210 (for example, directly above the first microchip 110B) also includes the opening V2. Through disposing the openings V2 in all the chip placement areas, no matter in which chip placement area the repair microchip 210 is placed, the pattern of a mask used when etching the second insulating layer 160 does not need to be readjusted.

What is claimed is:

1. A display device, comprising:
a substrate;
a plurality of first chip connection line structures, located above the substrate and extending outward from a chip placement area;
a plurality of light emitting elements, respectively disposed in a plurality of pixel areas around the chip placement area;
a first insulating layer, located above the substrate;
a failed microchip, located in the chip placement area, wherein the first insulating layer laterally surrounds the failed microchip, and the failed microchip is at least partially connected to the first chip connection line structures;
a plurality of second chip connection line structures, located above the first insulating layer, wherein at least a part of the second chip connection line structures is electrically connected to the first chip connection line structures; and
a repair microchip, located above the first insulating layer, wherein the repair microchip is located in the chip placement area and at least partially overlaps with the failed microchip, and the repair microchip is electrically connected to the light emitting elements through the second chip connection line structures.

2. The display device according to claim 1, wherein the first chip connection line structures are located between the first insulating layer and the substrate, the second chip connection line structures are located above the first insulating layer, and the second chip connection line structures are respectively filled into a plurality of first openings in the first insulating layer to be connected to the first chip connection structures.

3. The display device according to claim 2, further comprising:
a second insulating layer, located above the first insulating layer, wherein the light emitting elements are located above the second insulating layer, and the second chip connection line structures are located between the first insulating layer and the second insulating layer; and
a plurality of signal output structures, located above the second insulating layer, wherein the light emitting elements are respectively electrically connected to the signal output structures, and the signal output structures are respectively filled into a plurality of second openings in the second insulating layer to be connected to the second chip connection structures.

4. The display device according to claim 1, further comprising:
a second insulating layer, located above the first insulating layer and laterally surrounding the repair microchip, wherein the second chip connection line structures are located above the second insulating layer.

5. The display device according to claim 1, wherein at least one of the first chip connection line structures is cut to have a first part and a second part separated from each other, wherein the failed microchip is electrically connected to the first part, and at least one of the second chip connection line structures is electrically connected to the second part.

6. The display device according to claim 1, wherein the failed microchip comprises a plurality of first chip pads, and the repair microchip comprises a plurality of second chip pads, wherein the first chip pads are located on a side of the failed microchip close to the substrate, and the second chip pads are located on a side of the repair microchip close to the substrate.

7. The display device according to claim 1, wherein the failed microchip comprises a plurality of first chip pads, and the repair microchip comprises a plurality of second chip pads, wherein the first chip pads are located on a side of the failed microchip facing away from the substrate, and the second chip pads are located on a side of the repair microchip facing away from the substrate.

8. The display device according to claim 1, further comprising:
a plurality of signal input structures, extending outward from the chip placement area, wherein the signal input structures and the first chip connection line structures are located between the first insulating layer and the substrate;
a second insulating layer, located above the first insulating layer and the second chip connection line structures, wherein the second insulating layer laterally surrounds the repair microchip;
a plurality of bridging structures, wherein the bridging structures and the second chip connection line structures are located between the first insulating layer and the second insulating layer, and the repair microchip is electrically connected to the signal input structures through the bridging structures; and
a plurality of signal output structures, located above the second insulating layer, wherein the light emitting elements are respectively electrically connected to the signal output structures, and the repair microchip is electrically connected to the signal output structures through the second chip connection line structures.

9. The display device according to claim 1, further comprising:
a second insulating layer, located above the first insulating layer, wherein the second chip connection line structures are located above the second insulating layer;
a plurality of signal input structures, extending outward from the chip placement area, wherein the signal input structures and the first chip connection line structures are located between the first insulating layer and the second insulating layer; and
a plurality of bridging structures, located above the second insulating layer, wherein the repair microchip is electrically connected to the signal input structures through the bridging structures.

10. The display device according to claim 1, wherein a part of the first chip connection line structures is located between the repair microchip and the failed microchip.

11. A display device, comprising:
a substrate;
a plurality of light emitting elements, respectively disposed in a plurality of pixel areas around a chip placement area;
a first insulating layer, located above the substrate;
a first microchip, located in the chip placement area, wherein the first insulating layer laterally surrounds the first microchip; and
a second microchip, located above the first insulating layer, wherein the second microchip is located in the chip placement area and at least partially overlaps with the first microchip, and the second microchip is electrically connected to the light emitting elements; and
a first chip connection line structure, being cut to have a first part and a second part separated from each other, wherein the first microchip is electrically connected to the first part, and the second microchip is electrically connected to the second part.

12. The display device according to claim 11, wherein the first chip connection line structure is partially located between the first microchip and the second microchip.

13. The display device according to claim 11, further comprising:
a second insulating layer, located above the first insulating layer, wherein the first chip connection line structure is located between the first insulating layer and the second insulating layer;
a second chip connection line structure, located above the second insulating layer, wherein the second chip connection line structure is connected to the second part through a first opening in the second insulating layer.

14. The display device according to claim 11, further comprising:
a second insulating layer, located above the first insulating layer, wherein the first chip connection line structure is located between the first insulating layer and the substrate;
a second chip connection line structure, located above the first insulating layer, wherein the second chip connection line structure is connected to the second part through a first opening in the first insulating layer.

15. The display device according to claim 11, wherein the first microchip comprises a plurality of first chip pads, and the second microchip comprises a plurality of second chip pads, wherein the first chip pads are located on a side of the first microchip close to the substrate, and the second chip pads are located on a side of the second microchip close to the substrate.

16. The display device according to claim 11, wherein the first microchip comprises a plurality of first chip pads, and the second microchip comprises a plurality of second chip pads, wherein the first chip pads are located on a side of the first microchip facing away from the substrate, and the second chip pads are located on a side of the second microchip facing away from the substrate.
